(19) United States
(12) Patent Application Publication
(10) Pub. No.: US 2015/0309417 A1
(43) Pub. Date: Oct. 29, 2015

(54) EXPOSURE APPARATUS

(71) Applicant: LG CHEM, LTD., Seoul (KR)

(72) Inventors: Jeong Ho PARK, Daejeon (KR); Bu Gon SHIN, Daejeon (KR); Jae Jin KIM, Daejeon (KR); Jong Byung LEE, Daejeon (KR)

(21) Appl. No.: 14/647,389

(22) PCT Filed: Aug. 1, 2014
(86) PCT No.: PCT/KR2014/007147

§ 371 Date: May 26, 2015

(30) Foreign Application Priority Data
Aug. 1, 2013 (KR) 10-2013-0091793

(51) Int. Cl. G03F 7/20

(52) U.S. Cl. CPC G03F 7/70058; G03F 7/20

(57) ABSTRACT

Provided are a photomask, an exposure apparatus and a method. A fine pattern having a submicrometer size can be easily formed on a cylindrical mold, and the cylindrical mold having the pattern formed therein can be easily applied to an automation process, such as a roll-to-roll process. Also, the fine pattern can be formed in a large scale having various sizes by using a mask formed of a flexible material, and patterns having different shapes can be divided or independently formed on a curved surface of the cylindrical mold so that a degree of freedom of a process can be improved.

### BACKGROUND

1. Field of the Invention

The present invention relates to an exposure apparatus, an exposure method using the same, and a method of manufacturing a mold using the exposure apparatus.

2. Discussion of Related Art

A photolithography process is used in a method for forming a pattern when a semiconductor or a functional device is manufactured.

The photolithography process is a process of manufacturing a fine feature having a micrometer or nanometer size by transferring a shape of a photomask onto a substrate. For example, the photomask having a predetermined shape or pattern formed therein is placed on the substrate on which photoresist is coated, and light is irradiated onto the photomask. In this case, the irradiated light is selectively transmitted or blocked according to the shape or pattern formed in the photomask such that the photoresist coated on the substrate is selectively cured, the photoresist is removed after an etching process is performed and then, the predetermined shape or pattern can be formed on the substrate.

### SUMMARY OF THE INVENTION

The present invention is directed to an exposure apparatus in which a fine pattern having a submicrometer size can be easily formed on a mold that is an object onto which light is irradiated, and an exposure method using the exposure apparatus.

Hereinafter, an exposure apparatus according to the present invention will be described in greater detail with reference to the accompanying drawings. In the description of the present invention, detailed explanations of a well-known general-purpose function or configuration of the related art are omitted. Also, the accompanying drawings are schematic diagrams for understanding the present invention, and in order to clearly describe the present invention, unrelated portions to the explanations are omitted, and the scope of the present invention is not limited by the drawings.

The present invention is directed to an exposure apparatus. One embodiment of the present invention provides an exposure apparatus for forming a fine pattern on a surface of an object onto which light is irradiated, and an exposure method using the exposure apparatus.

An exposure apparatus according to an exemplary embodiment of the present invention may include: a light source 10; a photomask 30 that is disposed on a proceeding path of light emitted from the light source 10; and a holder 40 that is disposed on a path on which light that passes through the photomask 30 proceeds, as illustrated in FIG. 1. The photomask 30 may have one or more bumps 311 that are formed on an opposite surface to that of the light source 10, and a refractive index of the photomask 30 may be in the range of 1.2 to 2.5, 1.3 to 2.4, or 1.4 to 2.3. In detail, the photomask 30 may have an uneven surface 31 including the bumps 311 and grooves 310. Also, the holder 40 may be formed to hold an object (see reference numeral 20 of the following description) onto which light is irradiated, so that the surface of the object onto which light is irradiated is a curved surface. The exposure apparatus may form a fine pattern having a submicrometer size on the object onto which light is irradiated, by using the photomask 30 having the uneven surface 31 formed therein. By easily applying the exposure apparatus to an automation process, various patterns having the size of several hundreds of nanometers to several hundreds of micrometers are formed on the object onto which light is irradiated such that a convenience of a process can be achieved.

Also, the light source 10 and the bumps 311 may be formed to satisfy the following Equation 1.

ΔΦ=2π×(n₂−n₁)×d/λ [Equation 1]

wherein ΔΦ is a phase difference between light that is emitted from the light source 10 and passes through the bumps 311 of the photomask 30 and light that passes through the grooves 310 of the photomask 30 in which no bump is formed, and n₂ is a refractive index of the bumps 311 of the photomask 30, and n₁ is a refractive index of a medium filled in the grooves 310 of the photomask 30 in which no bump is formed, and d is a height of each of the bumps 311, and λ is a wavelength of the light emitted from the light source 10. λ in the above Equation 1 is a wavelength of the light irradiated onto the photomask 30, as described above, and may be a wavelength of light in a region of the G-line (436 nm), H-line (405 nm), and Mine (365 nm) of a general high-pressure mercury arc lamp or a wavelength of light using an excimer laser of KrF (248 nm), ArF (193 nm), and F2 (157 nm) so as to achieve higher resolution. A thickness of each bump 311 is controlled so that the height d of each bump 311 according to the light source 10 corresponds to an integer times π and thus the phase difference can be adjusted. Theoretically, if the phase difference ΔΦ satisfies only Equation 1, the height of each bump 311 may be any value; however, in consideration of an actual process, the height of each bump 311 may be 0.2 to 10 μm.

In an exemplary embodiment, FIG. 2 is a schematic diagram of the development of light interference that is performed in the uneven surface 31. As illustrated in FIG. 2, a phase difference of incident light occurs due to a difference between a refractive index of a medium filled in the bumps 311 and a refractive index of a medium filled in the grooves 310 at an interface between protruding portions of the uneven surface 31, i.e., the bumps 311 and recessed portions of the pattern, i.e., the grooves 310 of the pattern. In this case, the photomask 30 of the exposure apparatus according to the present invention may satisfy the condition of the above Equation 1. The medium may be air. In this case, a refractive index of light may be 1.

When ΔΦ is an integer times π in Equation 1, destructive interference occurs locally. In this case, a null point at which the intensity of light is close to zero, is formed in a partial region of a border between the grooves 310 and the bumps 311 of the pattern. Thus, the effect in which light does not reach photoresist 21, which will be described later, is shown at the null point. Thus, a fine pattern may be formed in a region in which the null point is formed.

FIG. 4 is a detailed view of light interference development that is performed in the region in which the null point is formed, and FIG. 5 is a view of a photoresist 21 which is generated by the development of light interference and then in which a fine pattern is formed.

In the present invention, the photoresist 21 is selected to absorb light in an ultraviolet region, for example, light having a wavelength of the Mine 350 to 380 nm, and when the irradiated light is light of a mercury lamp, due to the two factors of the absorption wavelength of the photoresist 21 and the wavelength of the irradiated light, a null point is formed where the bumps 311 of the photomask 30 and the photoresist 21 contact each other. Thus, a width of selection of a process condition is widened so that a degree of freedom of a process can be improved.

In addition, when a pattern having a size less than 1 μm, i.e., a submicrometer size, is formed using a general blank mask, a high-cost extreme ultraviolet light source needs to be used in consideration of a minimum CD and resolution of the pattern that may be acquired from a wavelength of a light source and a distance between the photomask and the substrate when an exposure process is performed. However, in the exposure apparatus according to the present invention, a pattern having a submicrometer size can be easily formed using a cost effective typical ultraviolet lamp as a light source.

In an exemplary embodiment, the exposure apparatus according to the present invention may further include an object 20 onto which light is irradiated, which is placed on the holder 40 while a surface of the object 20 onto which light is irradiated, is a curved surface. The object 20 onto which light is irradiated or the holder 40 may be placed on a proceeding path of light, and in detail, may be placed on a proceeding path of light that passes through the photomask 30. Also, the object 20 onto which light is irradiated or the holder 40 may have a roll shape. In detail, in an exemplary embodiment, the object 20 onto which light is irradiated, may be a cylindrical mold. In this case, as illustrated in FIG. 1, the holder 40 of the exposure apparatus may be a rotational apparatus that may rotate the cylindrical mold 20 around a central axis. Also, the exposure apparatus may further include a transferring unit 50 that transfers the photomask 30. The cylindrical mold 20 may be rotated at a constant speed of 0.01 to 500 mm/s in a fixed state in consideration of a convenience of design of the exposure apparatus and the exposure effect. Since the photomask 30 is transferred by the transferring unit 50 while the rotation speed and balance of the mold 20 are maintained, an exposure process may be performed in whole regions of the cylindrical mold 20.

In an exemplary embodiment, the object 20 onto which light is irradiated has a cylindrical shape, and a photoresist 21 may be formed on a surface of the object 20 onto which light is irradiated. When the cylindrical mold coated with the photoresist 21 is rotated on an upper portion of the photomask 30, as illustrated in FIG. 1, the photomask 30 is transferred by the transferring unit 50 in a horizontal direction, and light emitted from the light source 10 disposed below the photomask 30 is irradiated onto the photoresist 21 after passing through the photomask 30. For example, the photoresist 21 may be a positive resist or negative resist. Since the positive resist is developed only in a portion in which the null point, that will be described later, is formed, and the negative resist is not developed only in the portion in which the null point is formed, according to the present invention, an appropriate photoresist may be selected according to a user's desired shape and may be used.

In the present specification, the term [symbol] object onto which light is irradiated [symbol] is an object on which a fine pattern is formed, and the shape or material thereof is not particularly limited. For example, the object onto which light is irradiated, may be a mold having a flat surface or curved surface. In detail, the object onto which light is irradiated, may be a cylindrical mold, for example. However, the shape of the object onto which light is irradiated, is not limited thereto. In an exemplary embodiment, the object onto which light is irradiated, may be a mold having a surface coated with the photoresist, so that a fine pattern can be formed on the surface of the object onto which light is irradiated. Thus, in the following description, the term [symbol] object onto which light is irradiated [symbol] may be both a mold and a mold having a surface on which photoresist is formed.

In a specific embodiment of the present invention, the photomask 30 may include one or more bumps 311, for example. Each bump 311 may have a stripe shape, a curve shape, a polygonal shape, or a shape in which a stripe shape, a curve shape or a polygonal shape cross one another. However, the shape of each bump 311 is not limited thereto. In the present invention, the stripe shape may be a shape in which protruding portions of the fine pattern described above, i.e., the bumps 311, are arranged in parallel to each other at regular intervals. In an exemplary embodiment, the polygonal shape may be a shape in which one or more rectangular patterns are arranged in a lattice shape so as to be adjacent to each other, as illustrated in the pattern of FIG. 9. Also, the stripe shape, the curve shape, or the polygonal shape may be formed while these shapes cross one another. For example, each bump 311 may be formed in a shape in which the stripe shape or curve shape is connected to the polygonal shape. The crossing shape is not particularly limited thereto, and each bump 311 may be properly manufactured according to a technical field to which the present invention applies.

A material for forming the photomask 30 is not particularly limited. For example, the photomask 30 may include a flexible material through which ultraviolet rays are transmitted. A silicon-based resin, for example, may be used as the flexible material. In detail, a polydimethyl siloxane (PDMS) resin may be used as the flexible material.

When the photomask 30 includes the silicon-based resin, the photomask 30 has excellent light transmission in a wavelength region of 300 nm and thus may be effectively used in a photolithography process. Also, the photomask 30 has excellent adhesion with a base material and shows excellent contact when the photomask 30 and the photoresist contact each other, and a more excellent interference effect of light caused by formation of the null point can be shown.

In order to obtain resolution of a pattern and reliability in a photolithography process using an existing blank photomask, an air layer between the photoresist layer 21 and the photomask 30 is formed to a minimum thickness in order to obtain a minimum critical dimension (CD)(≈(λg)1/2) of the pattern so that contact between two interfaces can be maximized. That is, in a general contact exposure method, the minimum CD of the pattern is proportional to a distance g1/2 between the photomask 30 and the photoresist layer 21. To this end, a process of improving contact between two interfaces with appropriate pressure is necessary. However, since all of the substrates into which the photomask 30 and the photoresist layer 21 are introduced, are formed of a hard material, complete contact between two interfaces is not easy due to external foreign substances or surface roughness of the photomask 30 and the photoresist layer 21. Thus, a photolithography process technology has been suggested in which a mold that is transparent (has high transmittance of 70 to 80% of ultraviolet rays having a wavelength that is equal to greater than 300 nm) and has elasticity such as poly(dimethyl siloxane)(PDMS), is used as a mask. Since an elastic polymer has a low elastic modulus (or Young's modulus), a photomask formed of a silicon-based elastic polymer, such as PDMS can easily obtain very close contact with the photoresist layer 21.

In an exemplary embodiment, when the photomask 30 and the object 20 onto which light is irradiated, contact each other, the bumps 311 of the photomask 30 may contact the coated photoresist on the mold 20. The photomask 30 of the present invention causes the above-described interference development when the bumps 311 of the uneven surface 31 of the photomask 30 contact the photoresist 21 so that a fine pattern having a submicrometer size can be formed on the surface of the mold 20.

Also, as illustrated in FIG. 1, the exposure apparatus may further include a slit 60 that is formed between a collimated lens of the light source 10 and the photomask 30 and has an opening formed therein, the opening through which light emitted from the light source 10 may be transmitted and may be irradiated onto the photomask 30. Also, as illustrated in FIG. 3, the exposure apparatus may further include a slit 60 that surrounds the holder 40 and has the opening through which light emitted from the light source 10 may be irradiated onto the object 20 onto which light is irradiated, after passing through the photomask 30. Through the slit 60, the light emitted from the light source 10 may be irradiated onto the object 20 onto which light is irradiated and which is held by the holder 40, and in detail, may be irradiated onto the photoresist 21 of the object 20 onto which light is irradiated and on which the photoresist 21 is formed. The photomask 30 may be formed on a path on which the light proceeds, between the light source 10 and the holder 40, as illustrated in FIG. 3, and may be formed to surround the holder 40 or the object 20 onto which light is irradiated, this will be described later. In the latter case, the slit 60 may be formed to surround the holder 40 or the object 20 onto which light is irradiated, or the photomask 30 may be formed to surround the slit 60 that surrounds the holder 40 or the object 20 onto which light is irradiated. As described above, the exposure apparatus further includes the slit 60 so that the light emitted from the light source 10 can be more effectively transferred onto the object 20 onto which light is irradiated, i.e., onto a contact surface A between the photomask 30 and photoresist 21 and thus process efficiency can be further improved. That is, through the slit 60, a region to be exposed of the photoresist 21 coated onto the cylindrical base material can be enlarged, and an undesired interference pattern can be prevented from being formed according to an incidence angle of the light incident onto the photoresist 21 and a fine pattern having high reliability can be implemented.

Also, in an exemplary embodiment, the exposure apparatus may include the collimated lens or a condenser 70 disposed between the light source 10 and the slit 60. Also, the exposure apparatus may include a reflector 80 disposed at an opposite side to the slit 60 based on the light source 10.

FIG. 6 is a view of an exposure apparatus according to another embodiment of the present invention.

As illustrated in FIG. 6, in another embodiment of the present invention, the photomask 30 may be disposed to surround the holder 40 having the roll shape or the object 20 onto which light is irradiated or may be installed to be exposed using ultraviolet rays and the slit 60 in a circumferential direction while the holder 40 includes the photomask 30 or the object 20 onto which light is irradiated. That is, the holder 40 or the object 20 onto which light is irradiated, may be rotatably installed, and the object 20 onto which light is irradiated, may be held by the holder 40, and the photomask 30 may be installed to surround the holder 40 or the object 20 onto which light is irradiated.

When the exposure process is performed while the photomask 30 surrounds the object 20 onto which light is irradiated, as described above, the exposure process can be performed using only the holder 40 without using an additional transferring unit 50 so that an efficient process can be performed.

In this case, a diameter of the object 20 onto which light is irradiated, is not particularly limited but may be adjusted in consideration of a length of the photomask 30, and preferably, to minimize a joint. The “joint” is a portion that connects both ends of the photomask 30 that meet each other when the photomask 30 surrounds the mold 20 in the circumferential direction.

In one embodiment of the present invention, as illustrated in FIG. 7, two or more light sources 10 of the exposure apparatus may be disposed along an outside of the photomask 30 that surrounds the holder 40 or the object 20 onto which light is irradiated. The number of light sources 10 may not be particularly limited if light emitted from the light source 10 can be irradiated in all of a circumferential region of the holder 40 or the object 20 onto which light is irradiated and may be freely adjusted in consideration of cost and efficiency of the process.

In the present invention, the light source 10 is not particularly limited but may be an ultraviolet radiation lamp, for example.

The present invention is also directed to an exposure method using the above-described exposure apparatus. The exposure method according to an exemplary embodiment of the present invention includes exposing the surface of the object 20 onto which light is irradiated, using the exposure apparatus. That is, the exposure method according to the exemplary embodiment of the present invention includes disposing the object 20 onto which light is irradiated, on the holder 40 and exposing the object 20 onto which light is irradiated, by using the photomask 30 and radiating light from the light source 10.

In the exposure method according to the present invention, the exposure process can be performed by moving the object 20 onto which light is irradiated, or the photomask 30 by using the transferring unit 50.

Also, the object 20 onto which light is irradiated, may be a cylindrical mold coated with the photoresist 21, and the exposure process may be performed in a state in which the photomask 30 surrounds the cylindrical mold. In this case, as described above, two or more light sources 10 may be disposed along an outside of the photomask 30 that surrounds the holder 40 or the object 20 onto which light is irradiated. That is, light may be irradiated onto the photomask 30 that surrounds the cylindrical mold, by using a plurality of light sources 10.

In one embodiment, a wavelength of light irradiated in the exposure process may be a wavelength (including a wavelength range of ±30 nm from the center wavelength) in a region of the G-line (436 nm), H-line (405 nm), I-line (365 nm) of a high-pressure mercury arc lamp. Also, the wavelength of light irradiated in the exposure process may be a wavelength region using an excimer laser of KrF (248 nm), ArF (193 nm), and F2 (157 nm) so as to acquire high resolution. When light of the Mine (365 nm) of the high-pressure mercury arc lamp is used, the light with a quantity of light intensity of 3 to 25 mW/cm², for example, a quantity of light intensity of 5 to 20 mW/cm² or 10 to 15 mW/cm² may be irradiated for 0.01 to 5 minutes, for example, for 0.02 to 1 minute or for 0.05 to 0.5 minute.

In one embodiment, the object 20 onto which light is irradiated, may be a cylindrical mold 20 coated with the photoresist 21. The photoresist 21 is not particularly limited. However, the photoresist 21 may be the photoresist 21 that may absorb light in an ultraviolet region, for example, light having a wavelength of the Mine (365 nm) or 350 to 380 nm. The photoresist 21 may be coated on the cylindrical mold 20 to a thickness of 0.1 to 10 μm, for example, 0.2 to 1 μm or 0.3 to 0.8 μm. When the photoresist 21 is coated on the cylindrical mold 20 to an excessively large thickness that exceeds the above-described thickness range, a light radiation time is relatively increased so that an economical process cannot be easily performed.

In one embodiment, the exposure method may be performed by rotating the cylindrical mold 20 around a central axis of the mold 20 in the exposure process.

When the cylindrical mold 20 on which the photoresist 21 is coated, is rotated at the upper portion of the photomask 30, the photomask 30 is transferred in the horizontal direction, and light emitted from the light source 10 disposed below the photomask 30 passes through the photomask 30 and then is irradiated onto the photoresist 21.

The cylindrical mold 20 is rotated in the fixed state in consideration of a convenience of design of the exposure apparatus and the exposure effect, and a transparent base material in which the photomask 30 is included, may be rotated at a constant speed of 0.01 to 500 m/s, and the photomask 30 is transferred while the rotation speed and balance of the cylindrical mold 20 are maintained. Thus, the exposure process may be performed in entire regions of the cylindrical mold 20.

In another embodiment of the exposure method, in the exposure method may further include performing the exposure process in a state in which the photomask 30 surrounds the cylindrical mold 20. When the exposure process is performed in a state in which the photomask 30 surrounds the cylindrical mold 20, as described above, the process can be performed by only rotating the cylindrical mold 20 without transferring the photomask 30 so that an economical process can be performed.

In this case, the exposure process may be performed by radiating light onto the photomask 30 that surrounds the cylindrical mold 20, by using a plurality of light sources. In this case, the same exposure effect can be achieved without performing additional rotation.

In an exemplary embodiment, the exposure method according to the present invention may further include preparing and washing the cylindrical mold 20 before the photoresist 21 is coated on the cylindrical mold 20 and drying the photoresist 21 after the photoresist 21 is coated on the cylindrical mold 20. The drying process may be performed on condition, at 95 for 5 minutes, for example.

Also, in one embodiment, the exposure method according to the present invention may include additionally performing an etching process after the exposure process is performed. For example, the etching process may be performed by dry or wet etching.

The present invention is also directed to a method of manufacturing a mold. A method of manufacturing a mold according to an exemplary embodiment of the present invention may include forming a fine pattern on a surface of an object onto which light is irradiated, by exposing the surface of the object onto which light is irradiated, by using the above-described exposure apparatus. That is, the method of manufacturing the mold may be performed using the exposure apparatus or the exposure method according to the present invention. Also, as described above, the object onto which light is irradiated, may have a cylindrical shape, and a photoresist may be formed on the surface of the object onto which light is irradiated. In one embodiment, a pattern having a submicrometer size may be formed using the above-described exposure apparatus. In detail, the pattern may be configured of one or more lines, and widths of one or more lines may be in the range of 0.1 to 10 μm. Also, heights or depths of one or more lines may be in the range of 0.05 to 5 μm. Meanwhile, when one or more lines are formed using a positive resist, one or more lines may be developed only in a portion in which a null point is formed. Thus, one or more lines may be formed in the form of convex bumps. Also, when one or more lines are formed using a negative resist, one or more lines are not developed only in the portion in which the null point is formed. Thus, one or more lines may be formed in the form of concave grooves. Thus, when one or more lines are formed using the positive resist, line widths of the convex bumps may satisfy the above-described values, and when one or more lines are formed using the negative resist, line widths of the concave grooves may satisfy the above-described values.

### Effects

As described above, in an exposure apparatus according to the present invention, a fine pattern having a submicrometer size can be effectively formed on a cylindrical mold. Also, the fine pattern can be formed in a large scale having various sizes by using a mask formed of a flexible material, and patterns having different shapes can be divided or independently formed on a curved surface of the cylindrical mold so that a degree of freedom of a process can be improved.

### BRIEF DESCRIPTION OF THE DRAWINGS

FIGS. 1 and 3 are schematic views of an exposure apparatus according to an embodiment of the present invention;

FIG. 2 is a schematic view of an interference lithography process according to light interference development that is performed in a mask having an uneven surface;

FIG. 4 is a view of light interference development that is performed in a region in which a null point is formed, in more detail;

FIG. 5 is a view of a photoresist layer which is generated by the development of light interference and then in which a fine pattern is formed;

FIG. 6 is a schematic view of an exposure apparatus according to another embodiment of the present invention;

FIG. 7 is a schematic view of an exposure apparatus according to still another embodiment of the present invention;

FIG. 8 is a scanning electron microscope (SEM) photo of a surface of a photomask according to an exemplary embodiment of the present invention;

FIG. 9 is a SEM photo of a surface of photoresist exposed by the photomask;

FIG. 10 is a SEM photo of a surface of a mold from which the photoresist is removed, after an etching process is performed;

FIG. 11 is a SEM photo of a surface of a mold according to an embodiment of the present invention;

FIG. 12 is a SEM photo of a cylindrical mold having a pattern formed therein, according to an embodiment of the present invention; and

FIG. 13 is a SEM photo of a cylindrical mold having a pattern formed therein, according to another embodiment of the present invention.

### EXPLANATION OF THE MARKS IN THE FIGURES

10: light source
20: object onto which light is irradiated
21: photoresist
30: photomask
31: uneven surface
310: grooves
311: bumps
40: holder 50: transferring unit
60: slit
70: condenser
80: reflector
A: contact surface

### DETAILED DESCRIPTION OF EXEMPLARY EMBODIMENTS

The above-mentioned content will be described in more detail through the following examples and comparative example. However, the scope of the present invention is not limited to the following suggested embodiments.

### Example 1

### Manufacturing Photomask

After a G-line dedicated AZ1518 (AZ Electronic Materials) photoresist was coated on a glass substrate (110 mm×110 mm) at a speed of 1500 rpm using spin coating, the photoresist was dried at 95° C. for 3 minutes, thereby fabricating a film so that the thickness of final photoresist was about 3.5 μm, and a pattern was manufactured using a general photolithography process. After the photoresist was exposed at 20 m/Wcm² for 3.5 seconds using Karl Suss MA6 Mask Aligner equipment, the photoresist was developed in a development solution (CPD18) for about 5 minutes, was washed using distilled water and dried, thereby manufacturing a photomask.

A photomask formed of a polydimethyl siloxane (PDMS) resin, i.e., a PDMS(Sylgard 18, Dow Corning Corp.) mask mold was agitated so that the resin and the curing agent were uniformly mixed for about 30 minutes after a curing agent that contains a PDMS base resin and a platinum (Pt) catalyst was mixed at a mass ratio of 9:1. Subsequently, the PDMS mixture is poured on the pattern side of a photoresist (PR) pattern having a micro-structure that is release-treated using a fluorine-based silane material (release treatment is not essential but is preferable so as to repeatedly use the PR pattern used as a mold). Subsequently, the PDMS on PR pattern was left as it is for about 2 hours so that bubbles could release out from the PDMS resin on the PR mask mold and a PDMS resin mixture fully filled the micro-structure and then was completely cured in a convection oven at 60 to 70 for about 3 to 4 hours. Subsequently, a duplication PDMS pattern structure in which the mask mold was cooled down at a room temperature and then was cured, was release-peeled from the PR pattern and was formed. FIG. 8 is a scanning electron microscope (SEM) photo of a shape of the PDMS mold mask used in the current embodiment having a rectangular arrangement structure in which squares each of 100 μm×100 μm are arranged at an interval of 10 μm×10 μm.

<Photolithography Process for Flat Plate Type Mold>

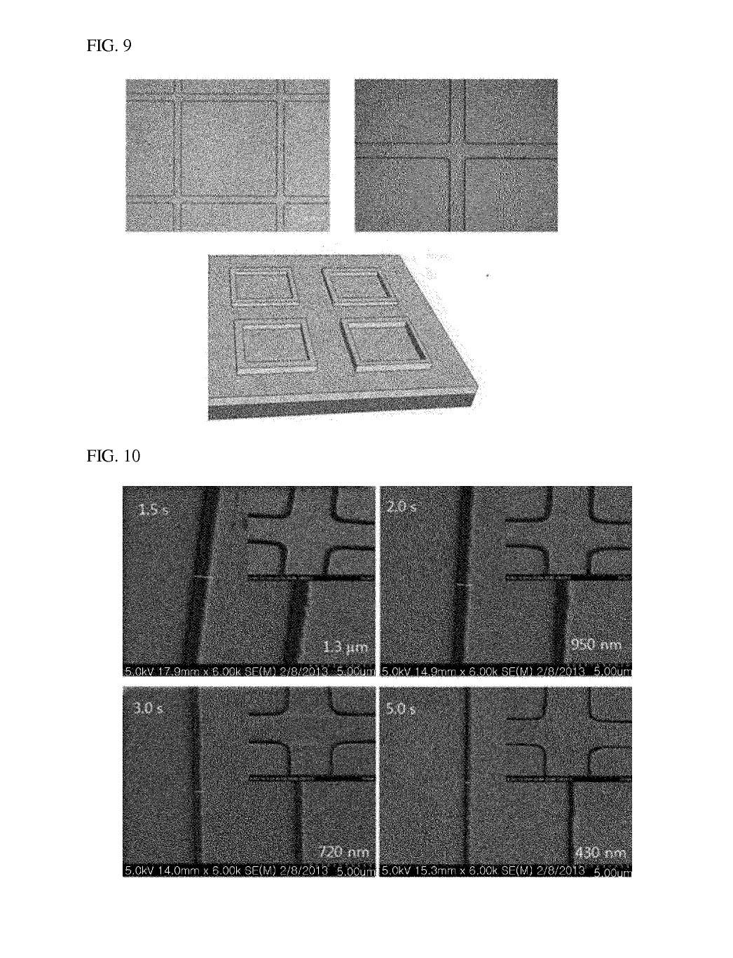

A solution in which propylene glycol monomethyl ether acetate (PGMEA) was diluted at a volume ratio of 75%, was prepared, and the G-line dedicated AZ 1518(AZ Electronic Materials) photoresist was coated on a quartz substrate to a thickness of 400 nm at 1500 to 2000 rpm for 30 seconds using spin coating. The photoresist was contacted with the photomask formed of the PDMS resin, was exposed using the Karl Suss MA6 Mask Aligner equipment at 15 to 20 mW/cm² for 1.5 to 5 seconds and then was developed in the development solution (CPD18) for about 10 seconds and was washed and dried, thereby forming a fine pattern having a submicrometer thickness as illustrated in FIG. 9. Checking a change in critical dimension (CD) of a pattern according to a process condition, it was found that the CD of the pattern is inversely proportional to an exposure time, as illustrated in FIG. 10.

<Etching Process for Flat Plate Type Mold>

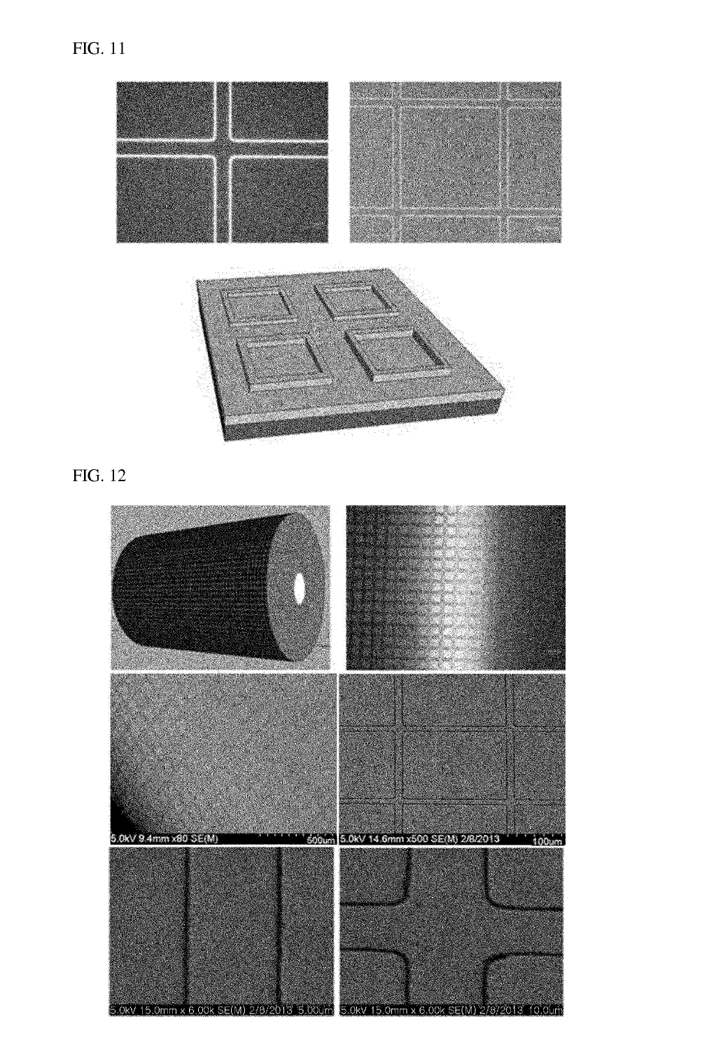

A submicro-pattern was formed on the quartz substrate in which an aluminum (Al) thin layer was generated to a thickness of 500 to 800 nm as a conductive thin layer using vacuum sputtering, by using the same process as the photolithography process, and molding was performed by dry etching (Working pressure 5 mTorr, ICP/RI power 300/30 W, Gas flow rate: BCl₃ 35, Cl₂ 15 sccm) using ICP-RIE (inductive coupled plasma-reactive-ion etching (ICP-RIE) and etching the Al layer using a phosphorus (P)-based aluminum etching solution, as illustrated in FIG. 11.

A flat plate type mold in which a submicro-shape is imprinted on a quartz base material, was manufactured using drying etching (Working pressure 2 Torr, ICP/RI power 1000/50 W, Gas flow rate: C₄F₈=30 sccm, Etching rate) using a fluorine-based gas or wet etching using 14% diluted hydrofluoric acid, as illustrated in FIG. 11.

### Example 2

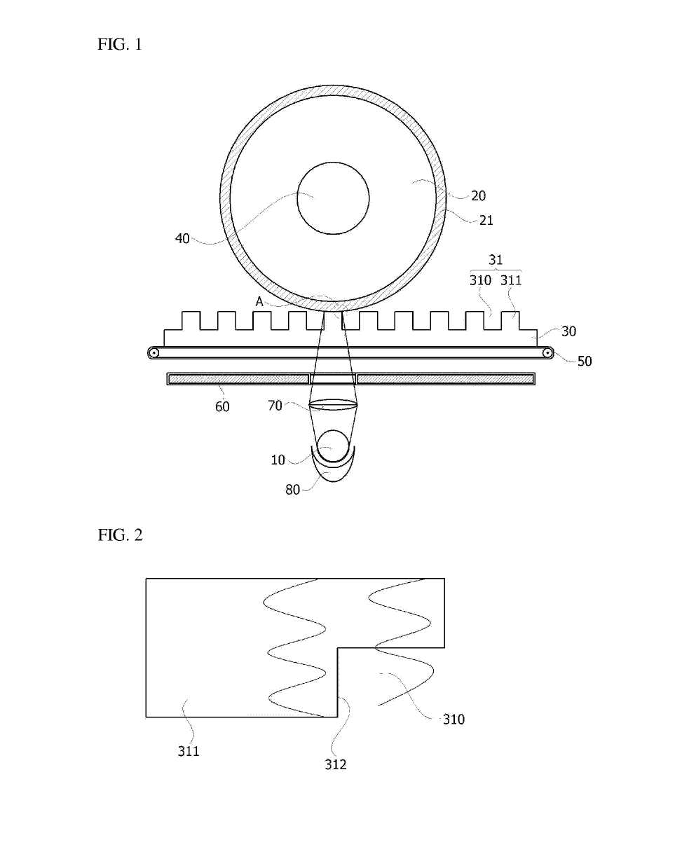

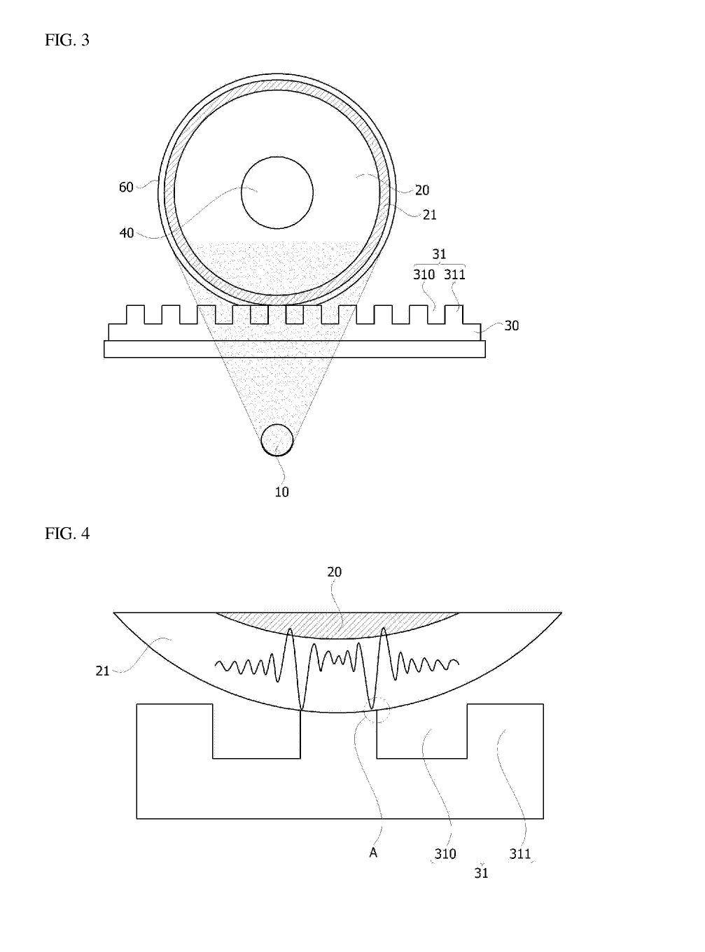

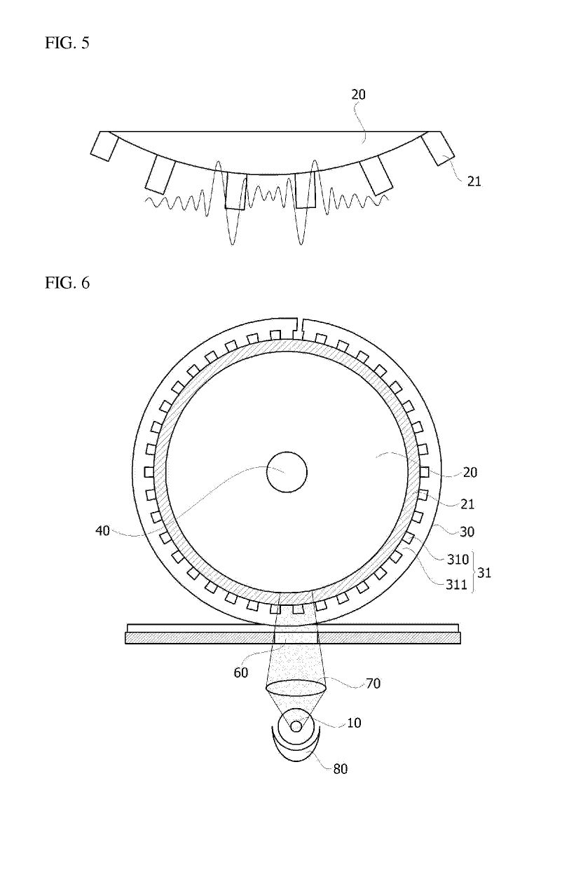

An exposure apparatus illustrated in FIG. 1 was prepared. Propylene glycol monomethyl ether acetate (PGMEA) was diluted at a volume ratio of 50%, and a cylindrical quartz mold having a diameter of 10 mm was cleaned, and an object onto which light is irradiated, was prepared by coating the G-line dedicated AZ 1518(AZ Electronic Materials) photoresist on the cylindrical mold to a thickness of 350 to 400 nm. Bumps on an uneven surface of the photomask in which a plurality of rectangular patterns having the uneven surface including bumps each having a width of 100 μm, grooves each having a width of 10 μm and with a height of 3.5 μm were formed using a PDMS resin, were placed to contact the photoresist. Subsequently, the photomask was transferred in a horizontal direction, and the object onto which light is irradiated, was rotated, and light of a high-pressure mercury arc lamp (wavelength of 365 nm) that is a light source disposed below the photomask, was irradiated with a radiation quantity of 20 mW/cm² at a transfer speed of 0.1 mm/s for about 5.2 minutes, thereby performing an exposure process. Development, washing and etching processes except for the exposure process were performed in the same manner as that of the Example 1, and an optical, electronic image of the manufactured mold was illustrated in FIG. 12.

### Example 3

An exposure process was performed in the same manner as that of Example 2 except for using the exposure apparatus illustrated in FIG. 6.

### Example 4

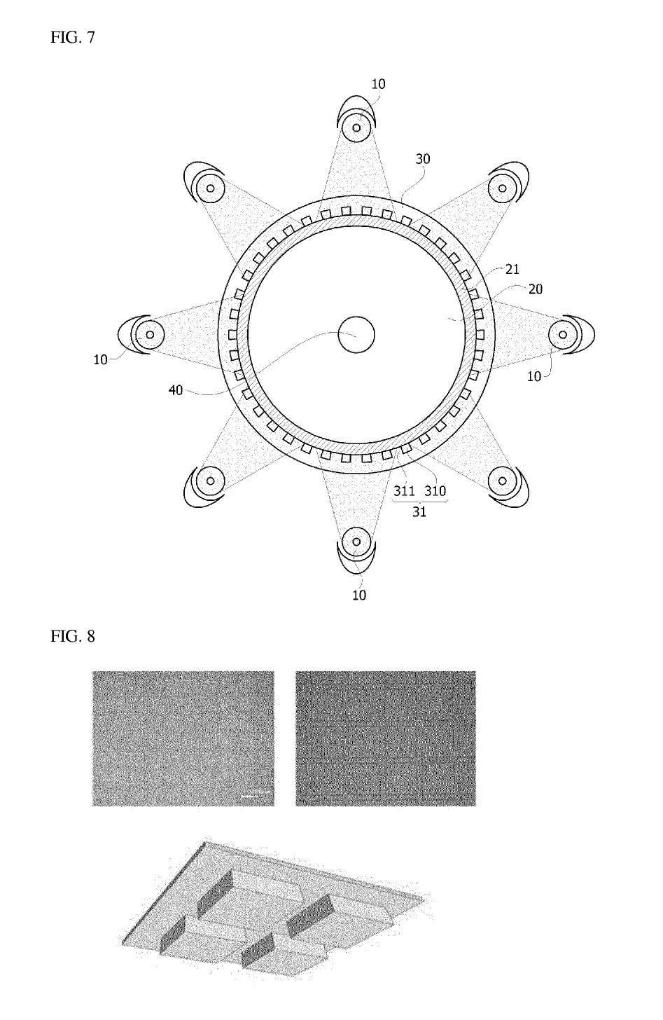

An exposure process was performed in the same manner as that of Example 2 except for using the exposure apparatus illustrated in FIG. 7.

### Example 5

An exposure process was performed in the same manner as that of Example 2 except for forming a pattern of a photomask having a hexagonal arrangement structure in which a plurality of regular hexagons each having a length of one side of 200 μm were formed as bumps and grooves were formed at an interval of 10 μm.

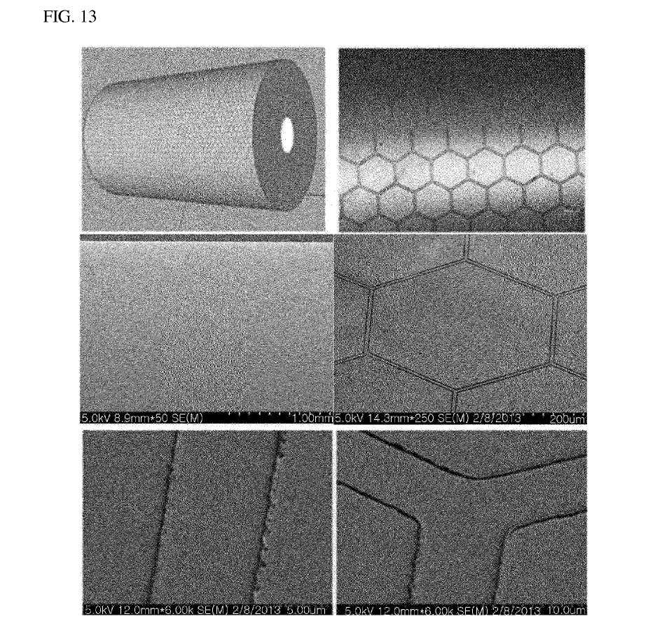

FIG. 13 is a SEM photo of a cylindrical mold having a pattern formed therein according to Example 5 of the present invention.

What is claimed is:

1. An exposure apparatus comprising:
a light source;
a photomask that is placed on a proceeding path of light emitted from the light source, has one or more bumps formed on an opposite surface to the light source and has a refractive index in a range of 1.2 to 2.5; and
a holder which is placed on a path on which light that passes through the photomask proceeds and on which an object onto which light is irradiated, is held so that a surface of the object onto which light is irradiated, is a curved surface.

2. The exposure apparatus of claim 1, wherein the light source and one or more bumps are formed to satisfy the following Equation 1:
ΔΦ=2π×(n₂−n₁)×d/λ, [Equation 1]
wherein ΔΦ is a phase difference between light that is emitted from the light source and passes through one or more bumps of the photomask and light that passes through grooves of the photomask in which no bump is formed, and n₂ is a refractive index of one or more bumps of the photomask, and n₁ is a refractive index of a medium filling in the groove of the photomask in which no bump is formed, and d is a height of each of one or more bumps, and λ is a wavelength of the light emitted from the light source.

3. The exposure apparatus of claim 1, further comprising an object onto which light is irradiated, which is disposed on the holder while a surface of the object onto which light is irradiated, is a curved surface.

4. The exposure apparatus of claim 1, wherein the holder has a roll shape.

5. The exposure apparatus of claim 3, wherein the object onto which light is irradiated, is a cylindrical mold.

6. The exposure apparatus of claim 1, wherein one or more bumps of the photomask has a stripe shape, a curve shape, a polygonal shape or a shape in which the stripe shape, the curve shape or the polygonal shape cross one another.

7. The exposure apparatus of claim 1, wherein the photomask has flexibility.

8. The exposure apparatus of claim 1, further comprising a slit that is formed between the light source and the photomask and has an opening formed therein, the opening through which light emitted from the light source is transmitted and irradiated onto the photomask.

9. The exposure apparatus of claim 1, further comprising a slit that is formed to surround the holder and has an opening formed therein, the opening through which light emitted from the light source is irradiated onto an object to be irradiated by the light, via the photomask.

10. The exposure apparatus of claim 8, further comprising a condenser that concentrates light from the light source so that light is capable of being irradiated into the opening.

11. The exposure apparatus of claim 4, wherein the photomask is disposed to surround the holder having a roll shape.

12. The exposure apparatus of claim 11, wherein the holder is rotatably installed.

13. The exposure apparatus of claim 11, wherein two or more light sources are disposed along an outside of the photomask that surrounds the holder.

14. A method of exposure comprising exposing a surface of an object onto which light is irradiated, using the exposure apparatus of claim 1.

15. The method of exposure of claim 14, wherein the object onto which light is irradiated, is a cylindrical mold coated with a photoresist, and an exposure process is performed in a state in which a photomask surrounds the cylindrical mold.

16. The method of exposure of claim 15, wherein light is irradiated onto the photomask that surrounds the cylindrical mold, using a plurality of light sources.

17. The method of exposure of claim 14, further comprising additionally performing an etching process after the exposure process is performed.

18. A method of manufacturing a mold, comprising forming a pattern on a surface of an object onto which light is irradiated, by exposing the surface of the object onto which light is irradiated, using the exposure apparatus of claim 1.

19. The method of claim 18, wherein the object onto which light is irradiated, has a cylindrical shape, and a photoresist is formed on the surface of the object onto which light is irradiated.

20. The method of claim 18, wherein the pattern is configured of one or more lines, and widths of the one or more lines are in a range of 0.1 to 10 μm.

21. The method of claim 18, wherein the pattern is configured of one or more lines, and heights or depths of the one or more lines are in a range of 0.05 to 5 μm.
